(19) United States
(12) Patent Application Publication
(10) Pub. No.: US 2022/0254955 A1
(43) Pub. Date: Aug. 11, 2022

(54) LIGHT EMITTING DIODE STRUCTURE

(71) Applicant: Lextar Electronics Corporation, Hsinchu (TW)

(72) Inventors: Cheng-Yu CHIEN, Hsinchu (TW); Hou-Jun WU, Hsinchu (TW); Chun-I WU, Hsinchu (TW)

(21) Appl. No.: 17/578,480

(22) Filed: Jan. 19, 2022

(30) Foreign Application Priority Data
Feb. 9, 2021 (CN) 202110177331.2

(51) Int. Cl. H01L 33/10

(52) U.S. Cl. CPC H01L 33/10

(57) ABSTRACT

A light emitting diode structure includes a metal reflective layer, a first transparent electrically-conductive layer, a dielectric layer, second transparent electrically-conductive layers, a first type semiconductor layer, an active layer and a second type semiconductor layer. The metal reflective layer has first concave sections. The first transparent electrically-conductive layer is conformally formed over the first concave sections of the metal reflective layer. The dielectric layer is formed over the first transparent electrically-conductive layer and has through holes to expose the first transparent electrically-conductive layer. The second transparent electrically-conductive layers are formed over the dielectric layer, and connected with the first transparent electrically-conductive layer via the through holes. Each second transparent electrically-conductive layer is connected to the first transparent electrically-conductive layer to form a T-shaped cross section in each first concave section.

### CROSS-REFERENCE TO RELATED APPLICATION

This application claims priority to China Application Serial Number 202110177331.2, filed Feb. 9, 2021, which is herein incorporated by reference in its entirety.

### BACKGROUND

### Field of Invention

The present disclosure relates to a light emitting diode structure.

### Description of Related Art

Light emitting diode is a light-emitting element made of semiconductor material that can convert electrical energy into light. It has the advantages of small size, high energy conversion efficiency, long life, power saving, etc., so it can be widely used as light source in various electronic applications.

Light emitting diodes with metal reflective layers often fail to achieve proper light extraction efficiency due to structural factors. In view of this, suppliers need various solutions to improve the light reflection efficiency of the metal reflective layer so as to achieve better light extraction efficiency.

### SUMMARY

One aspect of the present disclosure is to provide a light emitting diode structure, which includes a metal reflective layer, a first transparent electrically-conductive layer, a dielectric layer, a plurality of second transparent electrically-conductive layers, a first type semiconductor layer, an active layer and a second type semiconductor layer. The metal reflective layer has a plurality of first concave sections, and a convex portion is formed within each first concave section. The first transparent electrically-conductive layer is conformally formed over the first concave sections and the convex portions of the metal reflective layer. The dielectric layer is formed over the first transparent electrically-conductive layer and has a plurality of second concave sections, each second concave section having a through hole to a portion of the first transparent electrically-conductive layer that is aligned with the convex portion. The second transparent electrically-conductive layers are formed within the second concave sections respectively, and connected with the first transparent electrically-conductive layer via the through hole. The first type semiconductor layer, an active layer and a second type semiconductor layer are serially formed over the dielectric layer and the second transparent electrically-conductive layers.

Another aspect of the present disclosure is to provide a light emitting diode structure, which includes a metal reflective layer, a first transparent electrically-conductive layer, a dielectric layer, a plurality of second transparent electrically-conductive layers, a first type semiconductor layer, an active layer and a second type semiconductor layer. The metal reflective layer has a plurality of first concave sections. The first transparent electrically-conductive layer is conformally formed over the first concave sections of the metal reflective layer. The dielectric layer is formed over the first transparent electrically-conductive layer and has a plurality of through holes to expose the first transparent electrically-conductive layer. The second transparent electrically-conductive layers are formed over the dielectric layer, and connected with the first transparent electrically-conductive layer via the through holes, wherein each second transparent electrically-conductive layer is connected to the first transparent electrically-conductive layer to form a T-shaped cross section in each first concave section. The first type semiconductor layer, an active layer and a second type semiconductor layer are serially formed over the dielectric layer and the second transparent electrically-conductive layers.

In one or more embodiments, each second transparent electrically-conductive layer has a grain size larger than that of the first transparent electrically-conductive layer.

In one or more embodiments, an area sum of all the second transparent electrically-conductive layers is smaller than one-third of a total area of the first transparent electrically-conductive layer.

In one or more embodiments, an area of each second concave section is smaller than an area of each first concave section.

In one or more embodiments, an area of each second transparent electrically-conductive layer is smaller than an area of each first concave section.

In one or more embodiments, an area of the through hole is smaller or equal to an area of each second transparent electrically-conductive layer.

In one or more embodiments, each second transparent electrically-conductive layer has a grain size that is 2 to 5 times larger than that of the first transparent electrically-conductive layer.

In one or more embodiments, a convex portion is formed within each first concave section, and the convex portion is aligned with a corresponding one of the through holes.

In one or more embodiments, a convex portion is formed within each first concave section, and the convex portion is connected to the T-shaped cross section.

In summary, the light emitting diode structure disclosed herein reduces an area of the relatively rough transparent electrically-conductive layer so that it can still perform its ohmic contact function, while covering a thicker dielectric layer to reduce its roughness. The other transparent electrically-conductive layer with a relatively smooth surface covers the dielectric layer, and is connected to the relatively rough transparent electrically-conductive layer via the through hole on the dielectric layer such that the subsequently formed metal reflective layer has a larger flat and smooth area in order to increase the light reflection efficiency and light extraction efficiency.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a cross sectional view of a light emitting diode structure in accordance with an embodiment of the present disclosure; and

FIGS. 2-9 illustrate manufacturing steps of cross sectional views of a light emitting diode structure in accordance with various embodiments of the present disclosure.

### DETAILED DESCRIPTION

It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present disclosure. In addition, the illustrations may not necessarily be drawn to scale, and the identical elements of the embodiments are designated with the same reference numerals.

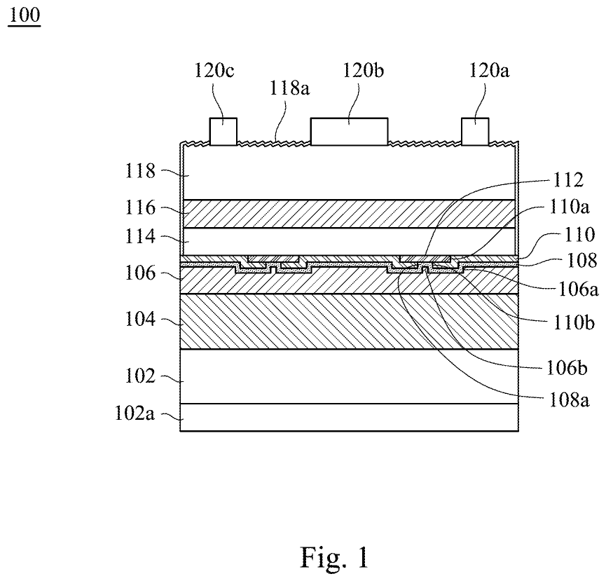

Reference is made to FIG. 1, which illustrates a cross sectional view of a light emitting diode structure in accordance with an embodiment of the present disclosure. The light emitting diode structure 100 includes a substrate 102, a metal reflective layer 106, a transparent electrically-conductive layer 108, a dielectric layer 110, a transparent electrically-conductive layer 112, a semiconductor layer 114, an active layer 116, and a semiconductor layer 118. In some embodiments of the present disclosure, the metal reflective layer 106 is made from materials that may include copper (Cu), aluminum (Al), indium (In), ruthenium (Ru), tin (Sn), gold (Au), platinum (Pt) , Zinc (Zn), silver (Ag), titanium (Ti), lead (Pb), nickel (Ni), chromium (Cr), magnesium (Mg), palladium (Pd) or any combinations thereof, but not being limited thereto. In some embodiments of the present disclosure, the metal reflective layer 106 has a plurality of concave sections 106a, and each concave section 106a has a convex portion 106b. In some embodiments of the present disclosure, the transparent electrically-conductive layer 108 is conformally formed over the concave sections 106a and the convex portions 106b of the metal reflective layer 106. The materials of the transparent electrically-conductive layer 108 may include transparent conductive oxide (TCO) or thin metal layer. For example, the transparent conductive oxide may include indium oxide (In₂O₃), indium tin oxide (ITO), tin oxide (SnO₂), Zinc oxide (ZnO), aluminum zinc oxide (AZO) or indium zinc oxide (IZO), but not being limited to this. The thin metal layer may include copper (Cu), aluminum (Al), indium (In), ruthenium (Ru), tin (Sn), gold (Au), platinum (Pt), zinc (Zn), silver (Ag), Titanium (Ti), lead (Pb), nickel (Ni), chromium (Cr), magnesium (Mg), palladium (Pd) or a combination thereof, but not being limited thereto.

In some embodiments of the present disclosure, the dielectric layer 110 is formed on the transparent electrically-conductive layer 108 and has a plurality of concave sections 110a, and each concave section 110a has a through hole 110b to expose the transparent electrically-conductive layer 108 and aligned with the raised portion 108a over the convex portion 106b. In some embodiments of the present disclosure, a plurality of transparent electrically-conductive layers 112 are located in these concave sections 110a respectively, and are connected to the raised portion 108a of the transparent electrically-conductive layer 108 via the through hole 110b.

In some embodiments of the present disclosure, the semiconductor layer 114, the active layer 116, and the semiconductor layer 118 are sequentially formed on the dielectric layer 110 and these transparent electrically-conductive layers 112. A portion of light beams emitted by the active layer 116 are directly output through an upper surface of the semiconductor layer 118, and the other portion of light beams are reflected by the metal reflective layer 106, and then output through the upper surface of the semiconductor layer 118.

In some embodiments of the present disclosure, the transparent electrically-conductive layer 108 has a smaller (crystal) grain size (i.e., compared with the transparent electrically-conductive layer 112) such that its surface is smoother. The metal reflective layer 106 that is in contact with the transparent electrically-conductive layer 108 also forms a smoother surface, which effectively reflects the light beams emitted by the active layer 116, thereby enhancing a light-emitting efficiency of the light emitting diode structure.

In some embodiments of the present disclosure, the transparent electrically-conductive layer 112 has a larger (crystal) grain size and serves as an ohmic contact layer with the semiconductor layer 114. Therefore, the transparent electrically-conductive layer 112 has a (crystal) grain size larger than that of the transparent electrically-conductive layer 108.

In some embodiments of the present disclosure, an area sum of all the transparent electrically-conductive layers 112 is less or smaller than one-third of a total area of the transparent electrically-conductive layer 108 such that a negative effect of the transparent electrically-conductive layer 112 with a larger (crystal) grain size on light emission can be reduced, but not being limited thereto.

In some embodiments of the present disclosure, an area of each concave section 110a is smaller than an area of a corresponding concave section 106a, but not being limited thereto. In some embodiments of the present disclosure, an area of each transparent electrically-conductive layer 112 is smaller than an area of a corresponding concave section 106a, but is not limited thereto.

In some embodiments of the present disclosure, a size, e.g., area, of the through hole 110b is smaller than or equal to an area of each transparent electrically-conductive layer 112. In some embodiments of the present disclosure, the (crystal) grain size of the transparent electrically-conductive layers 112 may be 2 to 5 times the (crystal) grain size of the transparent electrically-conductive layer 108, but not being limited thereto.

In some embodiments of the present disclosure, each transparent electrically-conductive layer 112 is connected to the raised portion 108a of the transparent electrically-conductive layer 108 to form a T-shaped cross section in each concave section 106a of the metal reflective layer 106. In some embodiments of the present disclosure, the convex portion 106b in the concave section 106a is connected to the T-shaped cross section.

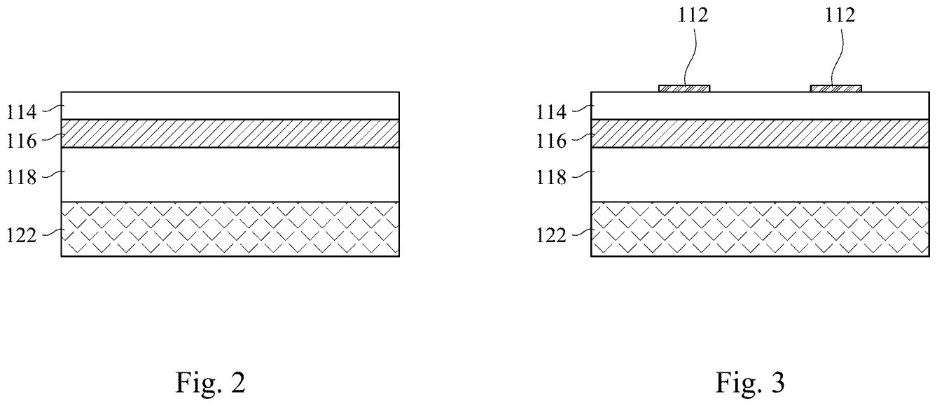

Reference is made to FIGS. 2-9, which illustrate manufacturing steps of cross sectional views of a light emitting diode structure in accordance with various embodiments of the present disclosure. In FIG. 2, a semiconductor layer 118, an active layer 116, and a semiconductor layer 114 are sequentially formed on a native substrate 122. In some embodiments of the present disclosure, the semiconductor layer 118 may be an N-type semiconductor layer, the active layer 116 may be a multiple-quantum well (MQW) layer, and the semiconductor layer 114 may be a P-type semiconductor layer.

In FIG. 3, a transparent conductive film is formed on a surface of the semiconductor layer 114, and patterned into a plurality of transparent electrically-conductive layers 112 each of which serves as an ohmic contact layer with the semiconductor layer 114. In some embodiments of the present disclosure, a shape (a top view shape) of each transparent electrically-conductive layer 112 may be a circle or an arbitrary polygon. In some embodiments of the present disclosure, a thickness of the transparent electrically-conductive layer 112 is at least 30 Angstroms or more, but not being limited thereto. The transparent electrically-conductive layer 112 has the characteristics of a larger (crystal) grain size and a large surface roughness, and serves as an ohmic contact layer with the semiconductor layer 114.

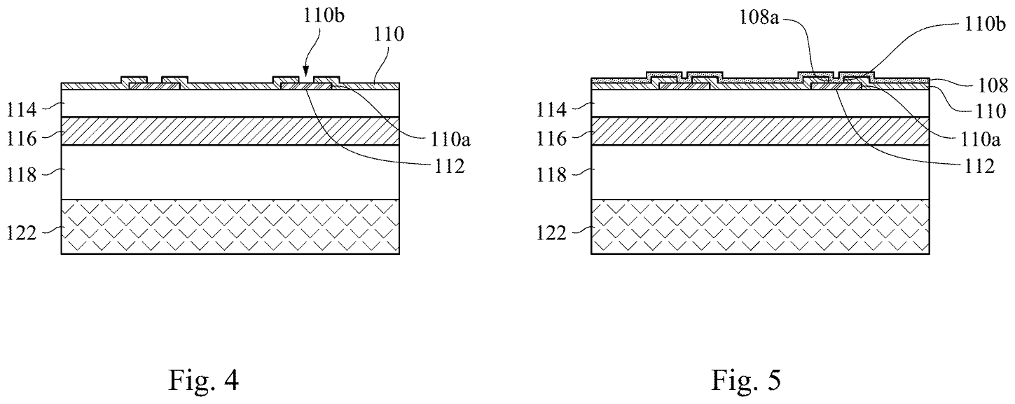

In FIG. 4, the dielectric layer 110 is conformally formed over the semiconductor layer 114 and those transparent electrically-conductive layers 112, thereby forming a plurality of concave sections 110a for accommodating those transparent electrically-conductive layers 112 respectively, and a through hole 110b is formed in each concave section 110a. In some embodiments of the present disclosure, a thickness of the dielectric layer 110 is at least 400 Angstroms or more, but not being limited thereto. A thicker dielectric layer 110 over the larger surface roughness of the transparent electrically-conductive layer 112 forms a smoother surface for an opposite side of the dielectric layer 110.

In FIG. 5, the transparent electrically-conductive layer 108 is conformally formed over a surface of the dielectric layer 110 to form a raised portion 108a, and the raised portion 108a is connected to the transparent electrically-conductive layer 112 via the through hole 110b. In some embodiments of the present disclosure, a thickness of the transparent electrically-conductive layer 108 is at least 50 Angstroms or more, but not being limited thereto.

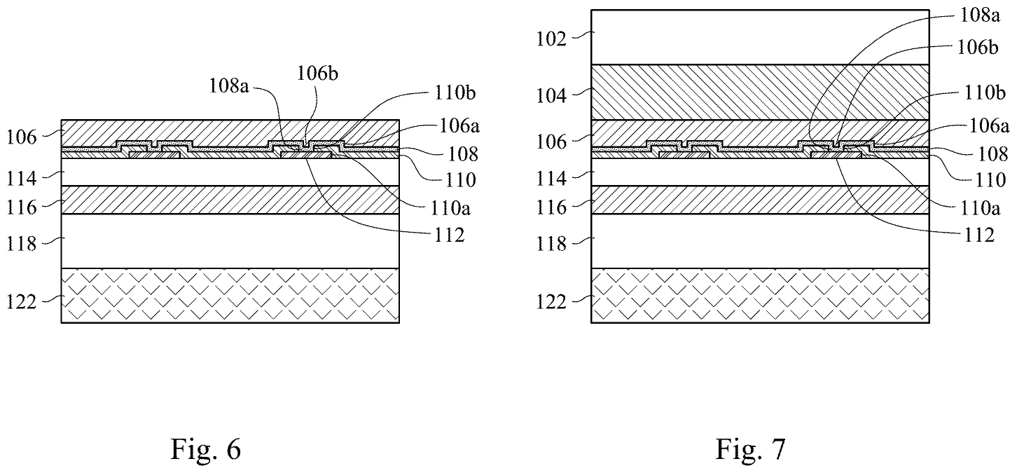

In FIG. 6, the metal reflective layer 106 is formed on the surface of the transparent electrically-conductive layer 108, thereby forming a plurality of concave sections 106a and convex portions 106b of the metal reflective layer 106, and each convex portion 106b is located in each concave section 106a. Because the transparent electrically-conductive layer 108 has a smaller (crystal) grain size and a smoother surface (compared with the transparent electrically-conductive layer 112), the metal reflective layer 106 has a surface that is in contact with the transparent electrically-conductive layer 108 and has a flatter and smoother surface for reflecting light beams.

In FIG. 7, a conductive bonding layer 104 is used to bond a metal substrate 102 to the metal reflective layer 106.

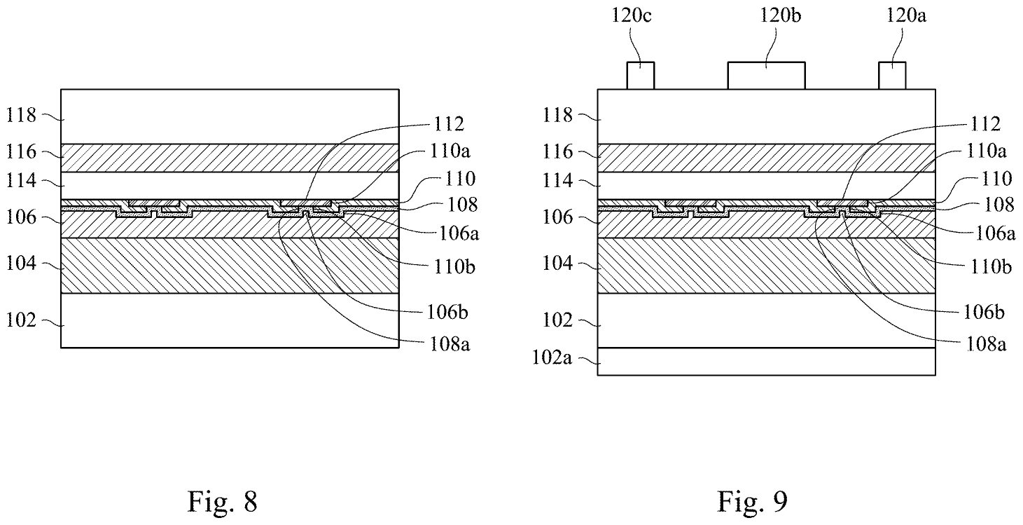

In FIG. 8, the structure completed in FIG. 7 is turned upside down, and the native substrate 122 is removed.

In FIG. 9, a multi-metal electrode layer (120a, 120b, 120c) is formed on the semiconductor layer 118, and a back metal layer 102a is formed under the metal substrate 102.

Referring to FIG. 1, a rough surface 118a is finally formed on the surface of the semiconductor layer 118 to increase the light extraction efficiency, and the light emitting diode structure 100 is completed.

In summary, the light emitting diode structure disclosed herein reduces an area of the relatively rough transparent electrically-conductive layer so that it can still perform its ohmic contact function, while covering a thicker dielectric layer to reduce its roughness. The other transparent electrically-conductive layer with a relatively smooth surface covers the dielectric layer, and is connected to the relatively rough transparent electrically-conductive layer via the through hole on the dielectric layer such that the subsequently formed metal reflective layer has a larger flat and smooth area in order to increase the light reflection efficiency and light extraction efficiency.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode structure comprising:
a metal reflective layer having a plurality of first concave sections, and a convex portion is formed within each first concave section;
a first transparent electrically-conductive layer conformally formed over the first concave sections and the convex portions of the metal reflective layer;
a dielectric layer formed over the first transparent electrically-conductive layer and having a plurality of second concave sections, each second concave section having a through hole to a portion of the first transparent electrically-conductive layer that is aligned with the convex portion;
a plurality of second transparent electrically-conductive layers formed within the second concave sections respectively, and connected with the first transparent electrically-conductive layer via the through hole; and
a first type semiconductor layer, an active layer and a second type semiconductor layer serially formed over the dielectric layer and the second transparent electrically-conductive layers.

2. The light emitting diode structure of claim 1, wherein each second transparent electrically-conductive layer has a grain size larger than that of the first transparent electrically-conductive layer.

3. The light emitting diode structure of claim 1, wherein an area sum of all the second transparent electrically-conductive layers is smaller than one-third of a total area of the first transparent electrically-conductive layer.

4. The light emitting diode structure of claim 1, wherein an area of each second concave section is smaller than an area of each first concave section.

5. The light emitting diode structure of claim 1, wherein an area of each second transparent electrically-conductive layer is smaller than an area of each first concave section.

6. The light emitting diode structure of claim 1, wherein an area of the through hole is smaller or equal to an area of each second transparent electrically-conductive layer.

7. The light emitting diode structure of claim 1, wherein each second transparent electrically-conductive layer has a grain size that is 2 to 5 times larger than that of the first transparent electrically-conductive layer.

8. A light emitting diode structure comprising:
a metal reflective layer having a plurality of first concave sections;
a first transparent electrically-conductive layer conformally formed over the first concave sections of the metal reflective layer;
a dielectric layer formed over the first transparent electrically-conductive layer and having a plurality of through holes to expose the first transparent electrically-conductive layer;
a plurality of second transparent electrically-conductive layers formed over the dielectric layer, and connected with the first transparent electrically-conductive layer via the through holes, wherein each second transparent electrically-conductive layer is connected to the first transparent electrically-conductive layer to form a T-shaped cross section in each first concave section; and
a first type semiconductor layer, an active layer and a second type semiconductor layer serially formed over the dielectric layer and the second transparent electrically-conductive layers.

9. The light emitting diode structure of claim 8, wherein each second transparent electrically-conductive layer has a grain size larger than that of the first transparent electrically-conductive layer.

10. The light emitting diode structure of claim 8, wherein an area sum of all the second transparent electrically-conductive layers is smaller than one-third of a total area of the first transparent electrically-conductive layer.

11. The light emitting diode structure of claim 8 further comprising a convex portion formed within each first concave section, the convex portion is aligned with a corresponding one of the through holes.

12. The light emitting diode structure of claim 8 further comprising a convex portion formed within each first concave section, the convex portion is connected to the T-shaped cross section.

13. The light emitting diode structure of claim 8, wherein an area of each second transparent electrically-conductive layer is smaller than an area of each first concave section.

14. The light emitting diode structure of claim 8, wherein an area of each through hole is smaller or equal to an area of each second transparent electrically-conductive layer.

15. The light emitting diode structure of claim 8, wherein each second transparent electrically-conductive layer has a grain size that is 2 to 5 times larger than that of the first transparent electrically-conductive layer.
